(19) United States
(12) Patent Application Publication
(10) Pub. No.: US 2011/0114173 A1
(43) Pub. Date: May 19, 2011

(54) METHOD OF MAKING SOLAR CELLS

(76) Inventors: Julie Baker, Watford Hertfordshire (GB); John Higgins, Pinner Middlesex (GB)

(21) Appl. No.: 13/055,781

(22) PCT Filed: Jul. 21, 2009
(86) PCT No.: PCT/US09/04212

§ 371 Date: Jan. 25, 2011

(30) Foreign Application Priority Data
Aug. 2, 2008 (GB) 0814174.9

(51) Int. Cl. H01L 31/0224; H01L 31/18

(52) U.S. Cl. 136/256; 438/62; 257/E31.001

(57) ABSTRACT

A method of creating a patterned particulate layer of a photovoltaic device comprises the steps of providing a dry powder to a fluidising unit, fluidising the powder to form a fluid flow and conveying the fluid flow to a printing unit. The printing unit has means to divert a variable amount of flow to a substrate and the remainder of the flow back to the fluidising unit.

### FIELD OF THE INVENTION

The present invention relates to the manufacture of dye-sensitised solar cells.

### BACKGROUND OF THE INVENTION

Dye-sensitized solar cells are a relatively new class of low-cost solar cells invented by Grätzel and O'Regan at the École Polytechnique Fédérale de Lausanne in 1991. The conventional form of these dye-sensitized solar cells, as described by Grätzel, consists of a transparent conducting substrate such as ITO on glass, on top of which is a sintered layer of dye coated titanium dioxide nanoparticles (the anode). A hole carrying electrolyte which typically contains iodide/tri-iodide as the electron (or hole) transfer agent is placed within the pores of and on top of this layer. The solar cell sandwich is completed by putting on top of the electrolyte a catalytic conducting electrode, often made with platinum as the catalyst (the cathode). When light is shone on the cell, the dye is excited and an electron is injected into the titanium structure. The excited, now positively charged dye oxidises the reduced form of the redox couple in the electrolyte to its oxidised form, that is, iodide goes to tri-iodide. This may now diffuse towards the platinum electrode. When the cell is connected to a load the electrons from the anode pass through the load to the cathode and at the cathode the oxidised form of the redox couple is reduced, that is, tri-iodide goes to iodide, completing the reaction.

Conventional methods of patterning the mesoporous nano-particulate layer include amongst others, extrusion coating, screen printing, gravure printing and spray coating.

U.S. Pat. No. 7,186,911 discloses a dye sensitised nanoparticulate material which may be deposited by applying a solution of metal oxide nanoparticles onto a substrate using suitable techniques such as extrusion coating, spray coating, screen printing and gravure printing.

U.S. Pat. No. 6,991,958 discloses a method of templating charge-carrier-transporting channel layers. These layers are formed by initially depositing a removable template on the conductive substrate that may include single or multi layers of nanoparticles e.g. polystyrene nanospheres. The layer of first charge-carrier-transporting material e.g. TiO₂ is then deposited on the template using techniques such as spin coating, casting, evaporation or any other technique known in the art for depositing a material on a substrate. The template is then removed.

U.S. Pat. No. 6,713,389 discloses a method of using a droplet deposition technique and a continuous inkjet printhead (and electrostatic spray head) to eject droplets of an array of custom fluids that when suitably dried/solidified on a specific surface form the elements of a solar cell (PV) device. Materials used in this process may include metallo-organics such as TiO₂.

GB 2427963 discloses a dye sensitised solar cell comprising a first patterned transparent conducting electrode with alternate sections of a second electrode layer and metal oxide dye sensitised layer. In this application, the patterned transparent electrode layer (e.g. ITO) is patterned using techniques such as contact printing, lithography etc. The second electrode layer (eg Pt) and the metal oxide layer (eg TiO₂) are both patterned using a mask.

WO 2007/098366 discloses a trace collection system and method for collecting traces of residues from an object for future analysis. One embodiment may include objects on a conveyor belt being printed upon using a print head. The ink used in the print head may comprise non-toxic particulates such as titanium dioxide, with no binder or a weak binder where the particles may be electrostatically adhered to the object. The particles may be directed to the object in a dry state or suspended in a liquid carrier, which then evaporates.

WO 2007/138348 discloses a photovoltaic cell comprising a photoelectrode, a counter electrode, a charge carrier material and a porous electrically insulating separator material disposed between the counter electrode and the charge carrier material. In one embodiment of this application, the photoelectrode is fabricated by electrostatic spraying of titania powder through a mask to create the desired areas of titania.

EP 1830430A1 discloses a photovoltaic device comprising a transparent support with a porous film formed on top. The porous film adsorbs the dye and contains a mixture of titanium dioxide particles doped with aluminium oxide and titanium dioxide particles not doped with aluminium oxide. In one embodiment the porous film is fabricated by coating the titanium dioxide paste (prepared by mixing the titanium dioxide particles with an acidic aqueous solution, a thickening agent and a dispersing agent) onto the support using a squeegee method, a screen printing method, a spray method or a direct jet printing method.

U.S. Pat. No. 7,019,391 discloses a system and method to dissipate heat from a semiconductor substrate including a nano ceramic material in thermal communication with a chip to remove heat from the chip. In one embodiment, nanocomposite powders are sprayed with a technique selected from plasma spraying, thermal spraying, powder spraying or electrostatically-assisted powder spraying.

In general, dry powder is applied as a surface coating by large-area spraying through a gun. Two types of powder coating systems are commonly used: corona guns and triboelectric guns. In both cases, the powder is fluidised in quantity by a gas flow, usually air, and pumped to a spray gun where it is electrically charged before being sprayed from the gun which is positioned some distance from the surface to be coated. The particles not deposited onto the surface, referred to as the overspray, are subsequently collected and, after taking steps to ensure that they are still of suitable quality, are reintroduced into the system.

The corona gun uses a high voltage generator to charge an electrode to a high potential (up to ˜100 kV) relative to the surface to be coated. The charged electrode disassociates air and generates a flood of charged particles, effectively charging the powder cloud as it passes through the gun, creating a charged field with the opposite pole, that is, the grounded surface. The charged powder particles exiting the gun then seek the lower potential of the grounded surface.

In contrast, the Tribo gun imparts a charge to the powder by physical contact between the powder and an internal surface in the gun that is capable of donating or receiving electrons. Polytetrafluoroethylene (PTFE or ‘Teflon’) is commonly used. Ambient humidity conditions affect charging and it is sometimes recommended that relative humidity does not exceed 50% and the compressed air dew point is maintained at no higher than 35° F. Various designs are known, for example those shown in U.S. Pat. No. 3,724,755 and U.S. Pat. No. 4,399,945.

When a corona gun is used, the primary force directing the material transport is the electric field established between the charged powder cloud and the grounded surface. In the tribo powder coating system, the primary means of material transport is the air flow used to fluidise the powder and carry it to the surface. In addition, in a tribo gun higher particle velocity results in better charging. In both cases, it is usual to ground the surface to be coated. The sprayed powder is subsequently immobilised on the surface, for example, by melting the powder in an oven.

In general, coarse powder particles charge more effectively than small particles; in this context the average particle diameter is usually 40 microns. It can be hypothesised that, as they have larger mass and greater momentum when propelled by the air stream, they impact the walls of a charging module more effectively and create greater frictional effects than smaller size particles, and so charge better. In any case, spraying smaller particle sizes is limited by health and safety considerations.

### PROBLEM TO BE SOLVED BY THE INVENTION

A key step in producing Grätzel cells is forming the patterned layer, typically 20 to 60 microns thick, comprised of titanium dioxide nano-particles. Thus, a relatively substantial laydown of dense nano-particulate material must be applied as a uniform layer to produce large area patterns on a support. Currently this is usually achieved in one of three ways. The powder can be coated using a volatile ‘carrier’ liquid or ‘vehicle’. Alternatively, the powder can be incorporated into an ink and printed. Thirdly, the powder can be sprayed, in which case the use of a volatile ‘carrier’ liquid is optional.

Each of these methods has some disadvantage. Coating can be achieved using one of a wide range of well-established methods such as slot-die coating, reverse roller coating, blade coating, etc., but in all cases drying is required, which can result in layer cracking, and some form of template is needed to produce a patterned layer. Printing the layer can produce patterns, but again some drying is necessary and extra addenda, vital to the printing process but often detrimental to cell performance, usually has to be incorporated into the ink and remains in the layer. Finally, even without the use of a vehicle, powder spraying cannot produce patterns without the use of a template and layer thickness is difficult to control, which increases waste and reduces efficiency. Variable patterning is not possible using any of these methods.

A more effective procedure is to apply dry particles directly to a surface to form the required patterns.

### SUMMARY OF THE INVENTION

In accordance with the present invention there is provided a method of manufacturing solar cells whereby a relatively substantial laydown of dense particulate material is applied directly as a uniform layer to produce patterns on a substrate. This is achieved by a variable printing process, distinct from the established spraying, printing or coating processes, in which very low concentrations of dry particles are introduced into a low velocity gas-flow and conveyed as a fluid through a pipe to a printing unit. The printing unit directs that part of the fluid flow intended for deposition through a small nozzle and onto the substrate; otherwise the fluid flow is recirculated back through the system.

According to the present invention there is provided a method of creating at least one patterned particulate layer of a photovoltaic device, comprising the steps of: providing a dry powder to a fluidising unit, fluidising the powder to form a fluid flow, conveying the fluid flow to a printing unit, the printing unit including a means to divert a variable amount of the fluid flow through a nozzle to a substrate, and recirculating the fluid flow not diverted to the substrate back to the fluidising unit, the fluid flow being continuously recirculated.

It is necessary to ensure that the fluid velocity issuing from the nozzle is sufficiently low to allow the nozzle to be positioned close to the substrate so that precise deposition can occur. In this way the fluid jet issuing from the nozzle remains largely focused in the form of a column of fluid. It is not necessary to ground the surface of the substrate.

Variable patterning of these layers can be achieved either by writing with one or more nozzles, or by using static arrays of nozzles when the substrate is moved accordingly, or both. Low fluid velocities limit the mass of powder conveyed to very low concentrations and as a consequence triboelectric particle charging can occur during conveyance from the fluidiser to the printing unit, at the printing unit, or in both circumstances.

### ADVANTAGES OF THE INVENTION

The present invention allows the manufacture of solar cells whereby layers comprised of dense powder particles are formed on a substrate in patterns that can be varied conveniently. It is especially applicable to roll to roll manufacturing. The method allows that no volatile carrier liquid, additional addendum or drying is required and as a consequence the layer-cracking often encountered upon drying is avoided and cell performance is improved. The overall structure, composition and form of the layer can be varied as needed. Multiple layers, of varying composition if required, can be deposited. No pattern templates are needed and the waste and inefficiency associated with using such devices are avoided. Without exceptional intervention, a significant level of particle cohesion and adhesion is produced such that the particles are anchored securely together and to the substrate in their patterned form for a considerable time after deposition.

### BRIEF DESCRIPTION OF THE DRAWINGS

The invention will now be described with reference to the accompanying drawings in which:

FIG. 1 is a schematic drawing of an apparatus for use with the method of the invention;

FIG. 2 is a copy of a photograph of a control cell;

FIG. 3 is a copy of a photograph of experimental cell A;

FIG. 4 is a copy of a photograph of experimental cell B;

FIG. 5 is a graph illustrating the performances of the control cell, cell A and cell B: and

FIG. 6 shows examples of titanium dioxide patterned layers printed using the method described in this invention.

### DETAILED DESCRIPTION OF THE INVENTION

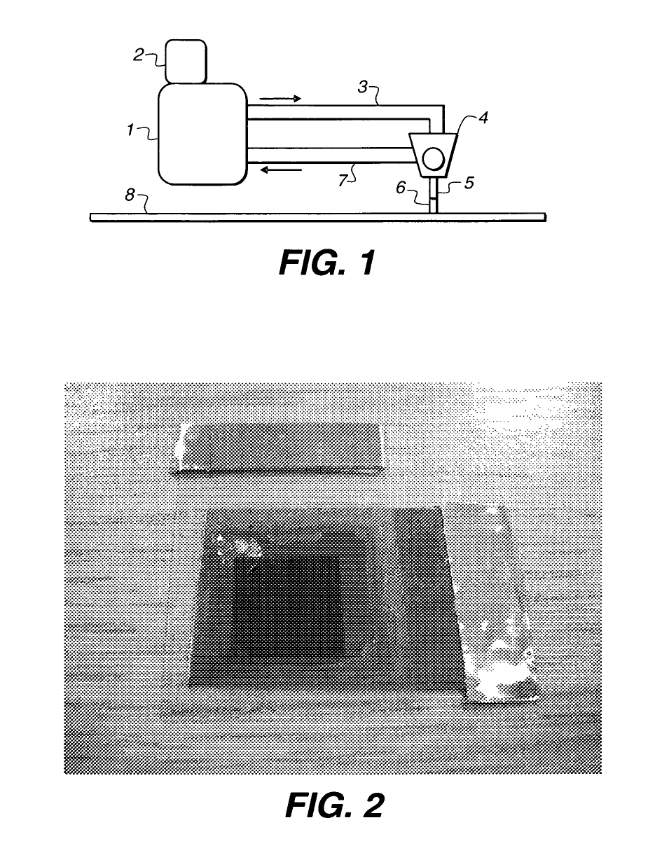

FIG. 1 is a schematic view of the apparatus used to perform the method of the invention. A powder supply unit 2 is connected to a fluidiser 1. A pipe 3 connects the fluidiser to a printing unit 4. ‘The printing unit is provided with a nozzle 5. Pipe 7 connects the printing unit back to the fluidiser 1. In use the apparatus is positioned above a substrate 8.

According to the present invention, dry powder is printed in the following way for the purpose of creating a solar cell. Powder is first fluidised in a very low velocity gas flow at very low concentrations before being conveyed through a pipe 3 to a printing unit 4. The printing unit 4 contains a valve which directs that part of the fluid flow intended for deposition through a small nozzle 5 and onto the substrate 8. That part of the flow not directed to the substrate is directed back to the fluidiser 1.

The powder particle size is less than a micron. The size is preferably less than 500 nm and more preferably less than 100 nm.

The nozzle 5 is positioned close to the substrate 8 and printing is achieved either by moving the nozzle over the substrate, moving the substrate under the nozzle, or both, in order to produce the desired pattern. This lends itself to a roll to roll manufacturing process. The distance between the nozzle and the substrate is between 1 mm and 40 mm, more preferably between 2 mm and 30 mm and most preferably between 3 mm and 20 mm.

The gas velocity issuing from the nozzle is between 0.1 and 2 m s⁻¹, more preferably between 0.2 and 1.5 m s⁻¹, and most preferably 0.3 and 1 m s⁻¹. The nozzle diameter is such that the turbulence for the fluid flow issuing from the nozzle, characterised by the Reynolds number, is between 1 and 100, more preferably between 2 and 50 and most preferably between 3 and 25, where

Reynolds number, Re=νDₙ/μ

(where ν=fluid velocity, Dₙ=nozzle internal diameter and μ=dynamic viscosity of the gas), that is, the ratio of inertial force to viscous force. An additional constraint on the nozzle diameter could be the precision required to print a feature, as the width of the nozzle approximates roughly to the minimum printed line width possible.

It is desirable that the diameter of the pipes 3 and 7, see FIG. 1, used to convey the fluidised powder to and from the printing unit is wider than the nozzle diameter. This helps avoid pipe blockages and particle aggregation during powder conveying. However, a wider pipe requires that fluid velocity in the pipe is proportionally lower than the fluid velocity in the nozzle. The exact pipe diameter can be deduced from the knowledge that gas velocity is inversely proportional to the square of the pipe diameter. Thus, if the pipe diameter is ten times bigger than the nozzle diameter, the fluid velocity in the pipe is one hundred times slower than the fluid velocity in the nozzle. In one embodiment of this invention the velocity of the powder jet ejected from the nozzle with an internal diameter of 0.5 mm is estimated to be 1 m s⁻¹, and so the velocity of the powder in a pipe with an internal diameter of 5 mm is very much less, only 0.01 m s⁻¹. Thus, as the amount of powder that can be transported through the pipe is proportional to the gas velocity in the pipe only very small quantities of powder are conveyed.

Pneumatic conveying systems are categorised in terms of the average particle concentration in the pipeline (see ‘Pneumatic conveying of solids’, Klinzing, G. E., Marcus, R. D., Rizk, F. and Leung, L. S., 2nd edition, Chapman and Hall, 1997). As only very small amounts of powder are conveyed in this invention, this system would be classed as ‘dilute phase’. The definition of a ‘dilute phase’ system is one with a mass flow ratio (μ), that is, the ratio of the solids mass flow rate (G) to the gas mass flow rate (Q), of less than fifteen.

Mass flow ratio, μ=(G/Q)≦15

for dilute systems (with G & Q in units of Kg s−1)
Perhaps a better mental picture of a dilute phase system can be obtained by considering the system ‘voidage’, ε, which describes the amount of space around the particles in a given pipe volume.

Voidage, ε=(V−Vₛ)/V

(where V and Vs are, respectively, the total pipe volume and the volume of solids enclosed within it) For a material with a density of 1300 kg m-3, a mass flow ratio value of 15 is equivalent to a voidage of 0.98, or 98% by volume. Thus the gas stream carries the material mostly as discrete particles. This occurs as long as the particle velocity is sufficient to avoid ‘saltation’, a condition when the particles flow in a surging, unstable fashion, and in this invention this limits the amount of powder conveyed.

Determining ‘saltation’ velocity, that is, the minimum fluid velocity required to avoid saltation for a fluid flow with a particular Mass Flow ratio, is important as it relates the amount of powder that can be conveyed in a pipe to the fluid velocity in that pipe. At this time this can be done only by using empirical equations. For example the equation due to Matsumoto et al (Matsumoto, S., Kikuta, M., and Maeda, S. (1977), J. Chem. Eng. Japan, 10, No. 2, 273) states:

$$Mass flow ratio , μ = 5.56 \times {{{10}^{3} [ \frac{d}{D} ]}^{1.43} [ \frac{{Fr}_{s}}{10} ]}^{4} \qquad ( 1 )$$

(where d=particle diameter in millimetres, D=pipe diameter in millimetres and Frₛ is the Froude number at the saltation velocity) and

Froude number, Fr=ν/\sqrt{gD}

(where ν=fluid velocity, D=pipe internal diameter and g=gravitational constant), the ratio of inertial force to gravitational force.

In one embodiment of this invention 20 nm titanium dioxide particles are fluidised and eventually jetted at velocity of 1 m s⁻¹ from a nozzle with an internal diameter of 0.5 mm. The particles are conveyed to the printing unit, and thus to the nozzle, through a pipe with an internal diameter of 5 mm at a velocity of 0.01 m s⁻¹. Under these conditions, according to equation (1) above, the maximum Mass Flow ratio is approximately of the order of 0.1, equivalent to a fluid flow containing less than 0.05% powder by volume. Such estimates are subject to large errors but serve to illustrate the principles by which this invention works. Even though only very small amounts of dry powder can be conveyed under these conditions it is deposited over a very small area, that is, approximately the cross-sectional area of the nozzle, in this case 0.2 mm². Alternative metal oxide particles that may be used in this invention include tin oxide (SnO₂), tungsten oxide (WO₃), zinc oxide (ZnO), niobium oxide (Nb₂O₅) and antimony oxide (Sb₂O₅) which may have particle diameters of less than 1 micron.

No deliberate efforts are made to obtain triboelectric effects, although they might be anticipated from the nature of this printing process. As only very small amounts of powder are conveyed, charging can occur as the powder is conveyed along the pipe especially by using, for example, pipes made or lined with a suitable polymer, such as PTFE. In the same way, charging can also occur in the printing unit. After printing, considerable adhesive and cohesive forces served to anchor the particles together in their patterned form, as well as to the surface, for a considerable time after deposition, see FIG. 6. These were sufficient even if the patterned layers were vigorously moved or exposed to moderate airflow. However, the strength and duration of these effects is unusually large.

After printing, the layers were processed using standard methods to create dye-sensitised solar cells.

### EXAMPLES

### Example 1

### The Control Cell

Titanium dioxide was dried in an oven at 90° C. overnight prior to use. This was a titanium dioxide sample which had an average particle size of 21 nm (Degussa Aeroxide P25, specific surface area (BET)=50+/−15 m²/g). The flexible dye sensitised solar cell was fabricated as follows.

Layers of mesoporous TiO₂ films approximately 30 μm thick were deposited onto the patterned 13 Ω/square ITO-PEN by dispersing the dried TiO₂ in a mixture of dry Methyl Ethyl Ketone and Ethyl Acetate in the following amounts:

| | |
|---|---|
| Degussa P25 TiO₂ (21 nm particles) | 1.35 g |
| Methyl Ethyl Ketone | 45 g |
| Ethyl Acetate | 5 g |

The resulting mixture was sonicated for 15 minutes before being sprayed over the entire area of conducting plastic substrate from a distance of approximately 25 cm using a SATAminijet 3 HVLP spray gun with a 1 mm nozzle and 2 bar nitrogen carrier gas. The layer was allowed to dry in an oven at 90° C. for one hour, before being placed between two sheets of Teflon, sandwiched between two polished stainless steel bolsters and compressed with a pressure of 3.75 tonnes/cm² for 15 seconds. The sintered layer was then allowed to dry for a further hour at 90° C.

The sample was then sensitised by placing it in a 3×10⁴ mol dm⁻³ solution of ruthenium cis-bis-isothiocyanato bis(2,2′bipyridyl-4,4′dicarboxylic acid) overnight. This sample was then used to construct a dye sensitised solar cell.

Platinum coated stainless steel foil electrodes were prepared by sputter deposition under vacuum.

The dye sensitised TiO₂ layer and the platinum counter electrode were arranged in a sandwich type configuration with an ionic liquid electrolyte in between. The electrolyte comprised:
0.1M LiI
0.6M DMPII (1,2,dimethyl-3-propyl-imidazolium iodide)
0.05M I₂
0.5M N-methylbenzimidazole
Solvent=MPN (Methoxypropionitrile)

This example constituted a Control cell. FIG. 2 shows the completed cell.

### Example 2

### Experiment cell A

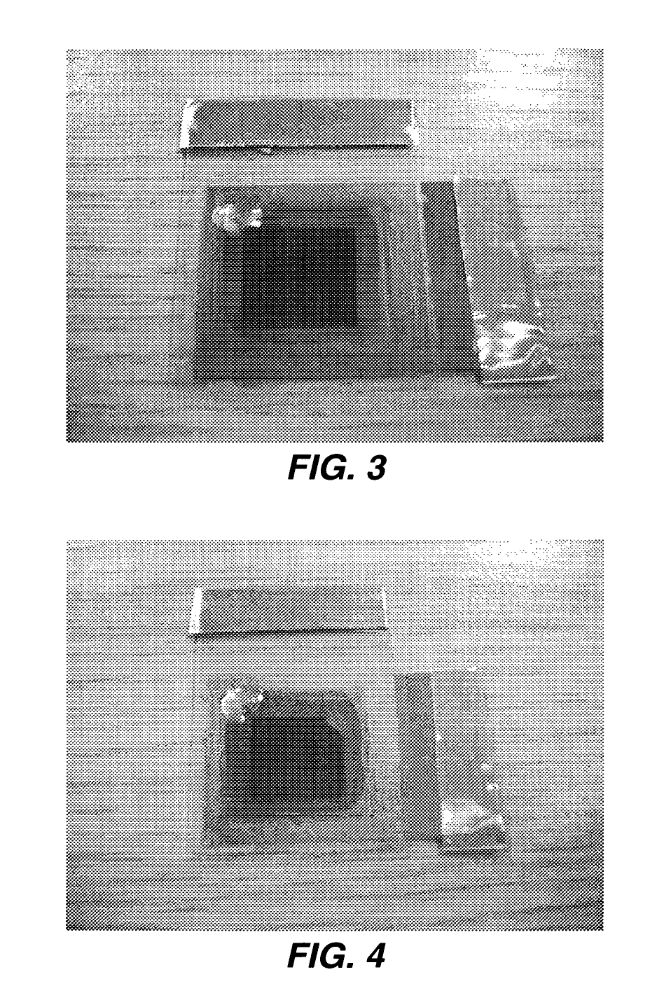

The material used in Example 1, titanium dioxide nanoparticles, supplied by Degussa as Aeroxide P-25, with an anatase:rutile ratio of approximately 80:20 and an average primary particle size of 21 nm, was printed using the method described above in accordance with the invention. In this example, the nanoparticulate powder was fluidised in air and eventually jetted at velocity of about 1 m s⁻¹ from a nozzle with an internal diameter of 0.5 mm, the nozzle comprising part of a printing unit. The particles were conveyed to the printing unit, and thus to the nozzle, through silicon tubing with an internal diameter of 5 mm. The concentration of powder in the fluid flow in the tubing was estimated to be less than 0.05% by volume. In this particular example, a patterned, thin powder layer was printed onto ITO-coated film first, before subsequently printing a more substantial patterned layer on top. The total laydown of titanium dioxide applied in this way was approximately equal to that by spraying in Example 1 above. FIG. 3 shows the completed cell.

The patterned layers printed in this way were subsequently made into solar cells using the procedure described in Example 1 above.

### Example 3

### Experiment cell B

The methods and procedures described in Example 2 were repeated, with the exception that approximately half the quantity of material was deposited to create this example, which was labelled Experiment cell B. Thus, the total laydown of titanium dioxide applied in this way was approximately half that applied by spraying in Example 1 above. FIG. 4 shows the completed cell.

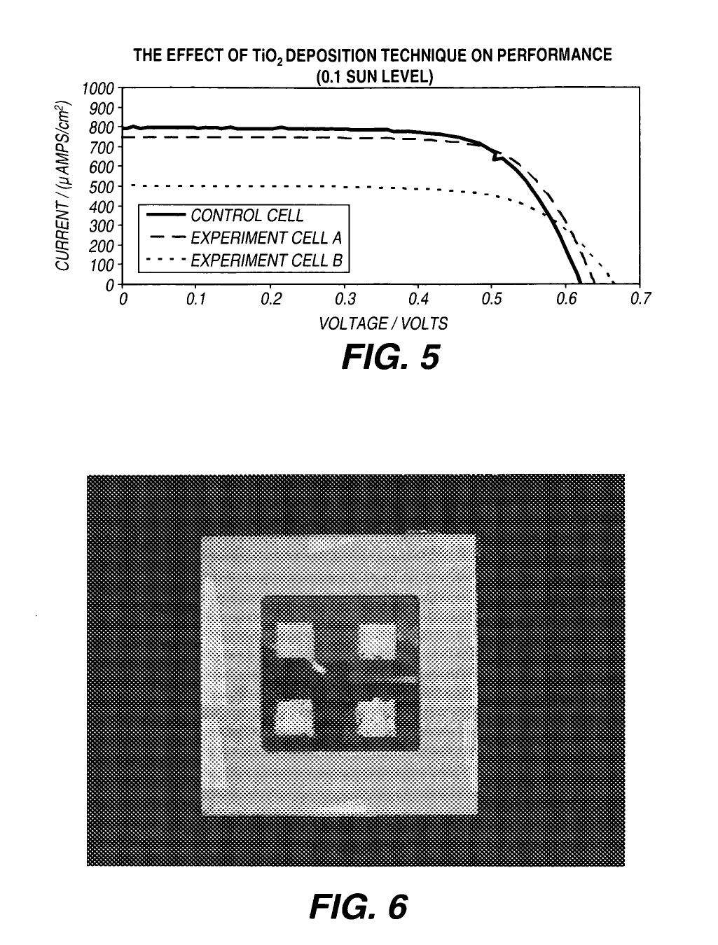

Following fabrication, the dye sensitised solar cells described in Examples 1, 2 and 3 were characterised by placing them under a source that artificially replicated the solar spectrum in the visible region to provide an illumination of 0.10 sun. The data obtained are given in FIG. 5 and show that the cells fabricated using the processes described above give appropriate results, that is, good current and voltage were achieved. The printed cells were compared to control cells made using the usual spraying method and the performances were found to be equivalent for equivalent laydowns.

While the performance of the dry powder printed cells was found to be as expected, an unusual feature of the invention was the robustness of the printed patterns. Once the particles were printed they were held in place only by the cohesive and adhesive forces produced during the jetting process. Vigorous movement of the sample or even exposing the layers to moderate directed airflow were insufficient to disturb the patterns. Samples printed and then stored for four months, although delicate, remained intact, see FIG. 6.

1. A method of creating at least one patterned particulate layer of a photovoltaic device, comprising the steps of
a. providing a dry powder to a fluidising unit,
b. fluidising the powder to form a fluid flow,
c. conveying the fluid flow to a printing unit, the printing unit including a means to divert a variable amount of the fluid flow through a nozzle to a substrate, and
d. recirculating the fluid flow not diverted to the substrate back to the fluidising unit, the fluid flow being continuously recirculated.

2. The method of claim 1, wherein the distance between the nozzle and the substrate is between 1 mm and 40 mm.

3. The method of claim 1, wherein the fluid velocity issuing from the nozzle is between 0.1 and 2 m s⁻¹.

4. The method of claim 1, wherein the nozzle diameter is such that the turbulence for the fluid flow issuing from the nozzle, characterised by the Reynolds number, is between 1 and 100.

5. The method of claim 1 using a plurality of printing units each having at least one nozzle.

6. The method of claim 1, wherein the printing unit or the substrate or both are moved to print powder patterns on a substrate.

7. The method of claim 1, wherein the powder particle size printed is less than 1 micron, more preferably less than 500 nm and most preferably less than 100 mn.

8. The method of claim 1 wherein that is part of a roll to roll manufacturing process.

9. A patterned particulate layer for use in a photovoltaic device manufactured in accordance with the method of claim 1.

10. A patterned particulate layer for use in a dye sensitized solar cell manufactured in accordance with the method of claim 1.
